(19) United States
(12) Patent Application Publication
(10) Pub. No.: US 2010/0091572 A1
(43) Pub. Date: Apr. 15, 2010

(54) 2T NOR-TYPE NON-VOLATILE MEMORYT CELL ARRAY AND METHOD OF PROCESSING DATA OF 2T NOR-TYPE NON-VOLATILE MEMORY

(76) Inventor: Woong Lim Choi, Suwon-si (KR)

Correspondence Address: Jae Y. Park, Kile, Goekjian, Reed & McManus, PLLC, 1200 New Hampshire Ave. NW, Suite 570, Washington, DC, 20036, US

(21) Appl. No.: 12/520,573

(22) PCT Filed: Nov. 21, 2007
(86) PCT No.: PCT/KR2007/005846

§ 371 Date: Aug. 12, 2009

(30) Foreign Application Priority Data
Dec. 22, 2006 (KR) 10-2006-0132823

(51) Int. Cl. G11C 16/04

(52) U.S. Cl. 365/185.18

(57) ABSTRACT

Provided are a 2-transistor (2T) NOR cell array which includes at least a cell, and a cell comprising a selection transistor and a storage transistor including a charge storage floating gate or a charge storage dielectric, and a method of processing data of a 2T NOR flash memory cell which is used to store data in a 2T NOR cell array, read the stored data, and erase the stored data. The 2T NOR cell array includes a selection transistor and a storage transistor. The selection transistor includes a terminal connected to a bit line and a gate terminal applied with a selection signal. The storage transistor includes a terminal connected to the other terminal of the selection transistor, the other terminal connected to a common source line, and a gate applied with a control voltage. A back bias voltage is applied to bulk regions of the selection transistor and the storage transistor when a programming operation is performed, and a floating gate or a charge storage dielectric is provided between the gate and the bulk region of the storage transistor.

### BACKGROUND OF THE INVENTION

1. Field of the Invention

The present invention relates to a NOR-type non-volatile memory, and more particularly, to a NOR-type non-volatile memory cell that is programmable with a low current and a low power and a method of processing data of the non-volatile memory. Examples of the non-volatile memory include a flash memory, an electrically erasable programmable read-only memory (EEPROM), a one-time programmable (OTP) memory, and the like.

2. Description of the Related Art

In a cell array of a NOR flash memory which is an example of a NOR-type non-volatile memory, hundreds of cells are connected in parallel at a single bit line. Here, a drain terminal of each cell is connected to the bit line, and a source terminal of each cell is connected to a common source line. Word lines are formed at predetermined intervals to be perpendicular to the bit line, and each word line is connected to a gate of each cell.

When a cell of the NOR flash memory is programmed, a hot carrier injection method is used, and when data programmed in the cell is erased, a Fowler-Nordheim tunneling (EN-tunneling) method is used.

In order to program a NOR-type cell implemented as an N-type MOS transistor by using the hot carrier injection method, a voltage of from 4V to 5V is applied to a drain electrode, and a voltage of about 9V is applied to a gate electrode, and a ground voltage is applied to a source electrode. In this case, the voltage of 9V is a relatively high voltage in terms of characteristics of a memory. Here, electrons move from the source electrode to the drain electrode along a channel, and the electrons are accelerated by a strong electric field that exists in a saturation region and therefore have high kinetic energy. A portion of the hot electrons that obtain high kinetic energy from the strong electric field overcome a potential barrier of a floating gate dielectric between a floating gate and the channel region and is injected into the floating gate.

The electrons injected into the floating gate are isolated by the potential barrier of the dielectric unless external change occurs, and this results in an increase in a threshold voltage of a storage transistor with respect to a control gate disposed at an upper portion of the floating gate, so that the memory is programmed. As a material for storing charge such as electrons, a dielectric disposed between the gate and the substrate may be used. As described above, similar to the case where charge is accumulated in the floating gate, in this case, the threshold voltage of the storage transistor is changed.

The FN tunneling is a physical phenomenon found by Fowller and Nordheim. In this phenomenon, when a high voltage is applied to two electrodes including a dielectric therebetween and a high electric field is formed at the dielectric, a tunnel current passing through the dielectric increases in an exponential function of the electric field. In a NOR structure in which electrons are isolated in the floating gate, a voltage of about −9V is applied to the control gate, and a voltage of about +8V is applied to a bulk electrode so as to erase the electrons by tunneling the electrons to the bulk region. By removing the electrons isolated in the floating gate, the threshold voltage of the cell transistor with respect to the control gate decreases unlike when the program operation is performed.

Since a bias voltage is not applied to a source or drain diffusion region of a cell when the erasing operation using the gate-bulk tunneling method is performed, a diffusion region area or a gate length of the cell are not influenced. On the contrary, in the FN tunneling method of erasing the electrons isolated in the floating gate by applying a bias voltage between the gate and the source or between the gate and the drain, a very high voltage has to be applied to the source or drain diffusion region, so that a size of the diffusion region also has to be increased. Therefore, there is a problem in that a memory cell size is significantly increased. This method is mainly used in the EEPROM, and also used in an early one-transistor (1T) NOR flash memory including a transistor.

The hot carrier injection method used in the 1T NOR cell has an advantage of a fast programming speed of a few to tens of microseconds but has a problem in that it needs a very high current of hundreds of micro-amperes (μA).

The 1T NOR memory cell array including a single storage transistor has a problem of over-erasure and disturb phenomena when programming and reading operations are performed.

The over-erasure problem means that when a cell of hundreds of cells connected to a bit line is unintentionally turned on by a physical error or a programming error, or a leakage current flows, another cell of a corresponding bit line cannot be read. Since the flash memory simultaneously erases hundreds of thousands of cells, stably controlling threshold voltages of hundreds of thousands of cells is physically impossible, and the threshold voltages when the erasing operation is performed have a statistic distribution. Here, fabrication and designing techniques have to be controlled so as not to generate an excessively erased cell.

Since the 1T NOR flash memory has the over-erasure problem, the 1T NOR flash memory cannot erase several erasure blocks simultaneously but has to erase an erasure block at a time. Therefore, there is a problem in that time consumed to erase the blocks and the entire chip of the 1T NOR flash memory is too long. For example, block erasion time of the 1T NOR flash memory with 256 Mbits is about 0.5 second, and chip erasure time is hundreds of seconds. On the contrary, a 2-transistor (2T) cell and a NAND-type cell transistor do not have the over-erasure problem due to a selection transistor. Therefore, an erasure speed increases, and blocks and the entire chip can be erased within tens of milliseconds. The over-erasure problem causes complexity of a chip circuit and extension of test time.

When the 1T NOR cell array programs or reads a cell, the same bit line voltage is applied to drain terminals of other cells of the same bit line as that of the cell, so that the cells that are not selected are influenced and may cause a change in data. This phenomenon is called disturb.

In addition, in the 1T NOR cell array, when programming operation is performed, a very high current of hundreds of micro-amperes (μA) is supplied to a bit line, and a very high voltage of from 4V to 5V is applied to a drain terminal of a cell, so that the 1T NOR cell array has a problem in that a large size of an area of a charge pump circuit is needed, and the number of cells that are programmed simultaneously is limited. As the number of cells that are programmed simultaneously decreases, a data programming speed decreases, and the slow data programming speed cannot be applied to a data storage application.

Due to high current characteristics of the hot carrier injection method of the 1T NOR cell, it is difficult to apply the hot carrier injection method to the 2T cell. More specifically, when an operation current is high, it is difficult to transfer a bit line voltage to a storage transistor through a selection transistor.

The operation method using a high current and a high voltage has a problem in that it is difficult to reduce a size of a cell and microfabrication cannot be easily performed.

### SUMMARY OF THE INVENTION

The present invention provides a 2-transistor (2T) NOR-type non-volatile memory cell array which includes a selection transistor and a storage transistor including a charge storage floating gate or a charge storage dielectric.

The present invention also provides a method of processing data of a 2T NOR-type non-volatile memory cell capable of performing a programming operation by using a hot carrier injection method with a low current and a low power.

According to an aspect of the present invention, there is provided a 2-transistor (2T) NOR-type non-volatile memory cell array which includes at least a cell, and a cell comprising a selection transistor and a storage transistor. The selection transistor includes a terminal connected to a bit line and a gate terminal applied with a selection signal. The storage transistor includes a terminal connected to the other terminal of the selection transistor, the other terminal connected to a common source line, and a gate applied with a control voltage. A back bias voltage is applied to bulk regions of the selection transistor and the storage transistor when a programming operation is performed, and a floating gate or a charge storage dielectric is provided between the gate and the bulk region of the storage transistor.

According to another aspect of the present invention, there is provided a method of processing data of a 2T NOR non-volatile memory. The method includes storing data in a NOR non-volatile memory which includes a selection transistor that has a terminal applied with a first voltage VD and a gate applied with a selection signal, and a storage transistor that has a terminal connected to the other terminal of the selection transistor, the other terminal applied with a second voltage VS, and a gate applied with a control signal, and reading or erasing the stored data. In the method of processing the data of the NOR non-volatile memory, a third voltage is applied to a bulk region of the selection transistor and a bulk region of the storage transistor, and a hot carrier injection method is used. Here, one or more voltage levels of the first voltage, the second voltage, the third voltage, and the control signal may be changed.

### BRIEF DESCRIPTION OF THE DRAWINGS

The above and other features and advantages of the present invention will become more apparent by describing in detail exemplary embodiments thereof with reference to the attached drawings in which:

FIG. 1 is a circuit diagram of a 2-transistor (2T) NOR-type non-volatile flash memory cell array according to the present invention; and

FIG. 2 illustrates a bias condition needed to store data in the 2T NOR-type non-volatile flash memory cell illustrated in FIG. 1, or read or erase the stored data.

### DETAILED DESCRIPTION OF THE INVENTION

Hereinafter, exemplary embodiments of the present invention will be described in detail with reference to the attached drawings.

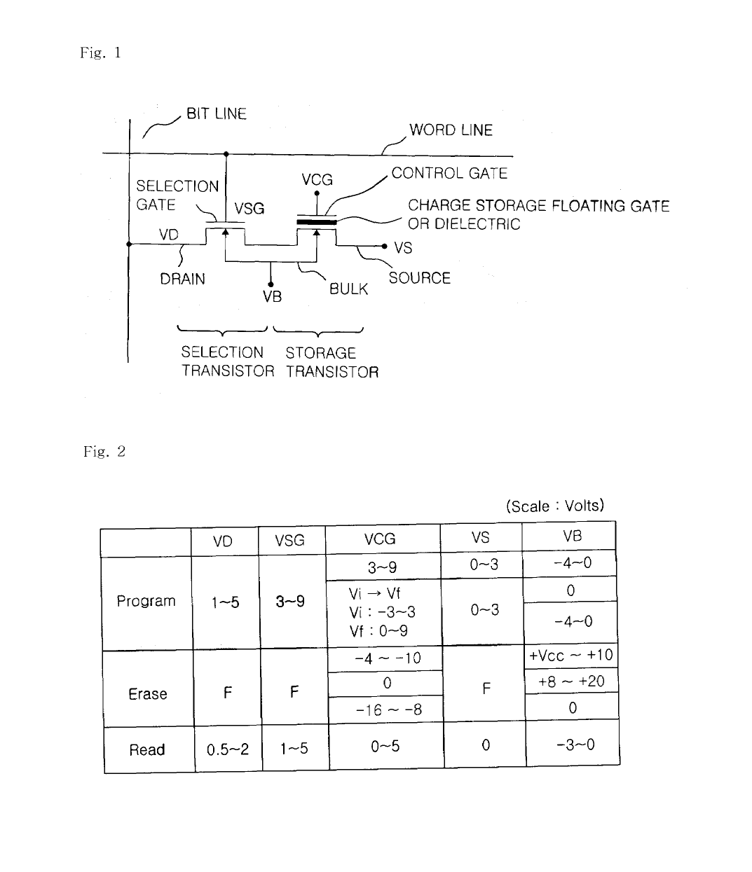

FIG. 1 is a circuit diagram of a 2-transistor (2T) NOR-type flash memory cell array according to the present invention.

Here, the 2T NOR-type flash memory cell may be applied to a cell array of another non-volatile memory cell such as an electrically erasable programmable read-only memory (EEPROM), a one-time programmable (OTP) memory, and the like.

Referring to FIG. 1, the 2T NOR-type flash memory cell array includes a selection transistor and a storage transistor. A terminal of the selection transistor is connected to a bit line VD and a gate of the selection transistor is applied with a selection signal VSG through a word line. A terminal of the storage transistor is connected to the other terminal of the selection transistor, the other terminal of the storage transistor is connected to a common source line VS, and a gate of the storage transistor is applied with a control signal VCG. A common bulk region of the selection transistor and the storage transistor is applied with a back bias VB.

Between the control gate of the storage transistor and a channel region, a charge storage floating gate or a charge storage dielectric exists. Here, the charge storage dielectric may be made of a material including one or more oxide layers and one or more nitride layers, or a material including tetrahedral amorphous carbon and one or more oxide layers. Examples of the charge storage dielectric include an oxide-nitride (ON) layer, an oxide-nitride-oxide (ONO) layer, and a tetrahedral amorphous carbon-oxide (TAG-O) layer, and the like.

In general, a gate dielectric of the selection transistor uses a silicon dioxide layer. In FIG. 1, the gate dielectric of the selection transistor and a gate dielectric of the storage transistor are the same or different from each other. However, as the gate dielectric of the selection transistor, the charge storage dielectric may be used. For the convenience of description of the present invention, the selection transistor and the storage transistor illustrated in FIG. 1 are N-type MOS transistors. However, the two MOS transistors are not limited to the N-type MOS transistors.

FIG. 2 illustrates a bias condition needed to store data in the 2T NOR-type flash memory cell illustrated in FIG. 1, or read or erase the stored data. Referring to FIG. 2, ranges of a voltage level of a bit line VD, a voltage level of a selection signal VSG, a voltage level of a control signal VCG, a voltage level of a common source line VS, and a voltage level of a back bias VB that are needed to store (or program) data in the flash memory, read the programmed data, and erase the programmed data, are illustrated. The voltage of the bit line is applied to a drain of a corresponding cell connected to the bit line, the voltage of the selection signal is applied to a gate of a selection transistor of the corresponding cell, the voltage of the control signal is applied to a gate of a storage transistor of the corresponding cell, the voltage level of the common source line is applied to a source of the corresponding cell.

When the selection transistor and the storage transistor are the N-type transistors, a voltage application condition of each node in order to program data in the storage transistor is as follows.

The voltage level of the first voltage VD ranges from 1V to 5V, the voltage level of the selection signal VSG ranges from 3V to 9V, the voltage level of the control signal VCG ranges from −3V to 9V, the voltage level of the second voltage VS ranges from 0V to 3V, and the voltage level of the third voltage VB ranges from −4V to 0V.

Here, the voltage level of the control signal VCG may be changed in a range of from an initial voltage level Vi that ranges from −3V to 3V to a final voltage level Vf that ranges from 0V to 9V in order to program data. This means that in order to store data in the storage transistor, the initial voltage of the control signal VCG is set to a voltage in the range of from −3V to 3V of the initial voltage level, and the final voltage thereof is set to a voltage in the range of from 0V to 9V of the final voltage level. For example, when the initial voltage is set to 0V and the final voltage is set to 6V, the voltage of the control signal VCG is changed to have the voltage level of 0V initially, be gradually increased, and have the voltage level of 6V finally.

Hereinafter, operations of storing data in the NOR memory cell array and reading or erasing the stored data, and a bias condition will be described with reference to FIGS. 1 and 2.

When the programming operation is performed, the selection transistor and the storage transistor are turned on, so that a current passes through the channel region of the selection transistor and the storage transistor and flows to the source terminal. Here, the applied gate voltage VSG of the selection transistor is higher than the bit line voltage VD so that the bit line voltage passes through the selection transistor and is sufficiently transferred to the drain terminal of the storage transistor. Here, a strong electric field is formed between the drain terminal and the source terminal of the storage transistor, and electrons supplied from the source terminal by the electric field are accelerated toward the surrounding of the drain region. The accelerated electrons are injected to the floating gate region or the charge storage dielectric of the storage transistor by a vertical electric field that is generated between the gate and the bulk of the storage transistor by the voltage VCG applied to the gate of the storage transistor.

Here, the back bias voltage VB is applied to the bulk region, a hot electron injection efficiency can be significantly increased. Specifically, a ratio of a gate current that is a program current for a drain current that is a supply current is increased, so that a bit line supply current needed to obtain the same gate current can be significantly reduced. In addition, since a program efficiency increases due to the back bias method, the voltage level of the bit line VD can also be reduced. Conventionally, it is difficult to apply the method of applying back bias to a conventional 1-transistor (1T) NOR cell array. Since hundreds of cells are directly connected to the same bit line without protected by selection transistors in a 1T NOR array structure, the aforementioned disturb phenomenon exists. When a programming speed or efficiency increases by applying the back bias, an effect of the disturb phenomenon also increases, so that there is a problem in that it is difficult to apply the back bias method to the 1T NOR cell array. According to the present invention, a selection transistor of each cell isolates a storage transistor of each cell from a bit line to protect the storage transistor, so that this problem is basically solved and the efficient back bias method can be applied.

In addition, when the hot carrier injection method is applied while the voltage of the control signal VCG applied to the gate terminal of the storage transistor is changed from the initial voltage level Vi to the final voltage level Vf, hot carriers can be injected into the floating gate or the charge storage dielectric with a low current and a low voltage. A channel current of a MOS transistor is proportionate to a difference between the voltage applied to the gate and the voltage applied to the source. Therefore, by maintaining the source voltage of the storage transistor at a certain degree and reducing the control gate voltage VCG, the channel current can be reduced.

In Firstly, by adjusting the voltage applied to the control gate lower than a final program threshold voltage value, the program current can be controlled with a very low level. As the programming progresses after applying a bit line voltage VD while the control gate voltage VCG is applied, the programmed threshold voltage increases and becomes saturated as time passes at a degree of the control gate voltage VCG or less or a little more. However, when the control gate voltage is increased after the programming operation is performed for a predetermined time, more hot carriers are injected again into the floating gate and the charge storage dielectric more rapidly. Therefore, by repeating this procedure until a target programmed threshold voltage is obtained, the hot carrier injection programming can be achieved with very low current value and with a fast speed, as well.

Here, the bit line voltage may be applied in a type of a pulse or linearly increased. The voltage of the control gate may have a type of a stair, a pulse, or linear increase or may have a mixed type thereof. When the programming operation is performed, the initial voltage level Vi and the final voltage level Vf applied to the gate of the storage transistor may be controlled according to a desired program threshold voltage value. The initial gate voltage Vi may be properly controlled so that a problem in an initial program due to an excess current does not occur.

Here, a rate of increase of the control gate voltage VCG applied to the gate of the storage transistor is adjusted to control a program operation current within a target value. In addition, the back bias method is applied thereto, the program can be effectively implemented with a low voltage and a low current. In this manner, using a very low drain current of tens or hundreds of nano-amperes (nA), a high-speed programming operation within a few or tens or hundreds of microseconds can be performed.

Therefore, by properly controlling an operation bias condition, a program time of a few micro seconds in a NOR-type level or a program time of tens or hundreds of microseconds in a NAND-type level can be implemented in a very low current and very low voltage values.

In this new method of programming, since such a low current of tens or hundreds of nano-amperes flows through each cell (or bit line), thousands of cells can be simultaneously programmed without the increase of circuit area and power consumption of the corresponding charge pump circuit. In the 1T NOR cell array, a high current of hundreds of micro-amperes is consumed for each bit line voltage 4.5V during programming. In this case, a large number of cells cannot be programmed simultaneously due to a limitation to a charge pump current. In general, 8 cells or more or less are programmed simultaneously. On the other hand, in the array according to the present invention, a very low current of a few micro-amperes or tens or hundreds nano-amperes is consumed for each bit line with a bit line voltage of about 4V or less, so that thousands of cells can be simultaneously programmed.

Accordingly, the programming operation can be performed in a very fast data processing speed. The NAND cell is programmed using FN tunneling, so that a consumed current is very low, and a data writing speed increases due to the high-speed parallel program. According to the present invention, using the NOR-type hot carrier injection method, the high-speed programming operation in the NAND level can be performed.

When data is programmed in the memory cell array, the programming operation is performed by applying the back bias voltage VB or changing the control voltage VCG, or simultaneously changing the control voltage VCG and the back bias voltage VB. In this way, as compared with a conventional method performed in a memory cell, the present invention has an advantage in that the operation can be performed with a low consumption current and a low voltage.

As described above, the NOR memory cell array according to the present invention has a structure including the selection transistor, and the cell array is programmed by applying the low current and low voltage hot carrier injection program method to the structure. Accordingly, there are advantages as follows.

First, an operation voltage decreases when the programming operation is performed. More specifically, when the FN tunneling method is applied as in the conventional art, a voltage of a gate or a word line of a cell is about 18V, and a voltage applied to a diffusion region is about 18V. However, according to the present invention, the hot carrier injection method is used for the NOR memory cell array, so that the voltage of the gate or the word line is decreased to 10V or much less, and the voltage applied to the diffusion region is decreased to 5V or much less.

Second, the gate voltage is increased from a low voltage at a constant back bias voltage when the programming operation is performed, a very low cell program current less than a few micro-amperes (μA) is used to perform the programming operation. In addition, by controlling the rate of increase of the gate voltage, the cell program current may be decreased to hundreds of nano-amperes (nA) or less.

Third, since the NOR memory cell array according to the present invention has the structure including the selection transistor, problems of over-erasure, bit line disturb, and a bit line leakage current in a conventional NOR cell can be solved.

Fourth, the method using a low current and a low voltage is applied, so that an area of a peripheral circuit can be significantly reduced as compared with a conventional NAND flash memory and a conventional NOR flash memory. In general, a ratio of a circuit area to the entire chip of the NOR flash memory approaches 60%. Therefore, by reducing the circuit area in the method using the low voltage and the low current, a chip size can be effectively reduced.

Fifth, the hot carrier injection method using a low current and a low voltage is applied, so that a cell size can be significantly reduced as compared with the conventional 2T EEPROM, and a small cell size as in the conventional 1T NOR flash memory level can be implemented even in the 2T cell structure.

Last, due to the back bias effect and an effect of the low current and low voltage, scalability of the cell according to miniaturization in lithography can be significantly improved. The back bias reduces punch-through and snapback in a direction of a channel length and reduces a size of a field region in a direction of a channel width. Therefore, there is an advantage in that the scalability of a cell is significantly improved.

Referring to FIG. 2, in order to erase data stored in the cell array, the bit line VD, and the gate VSG and the source VS of the selection transistor are allowed to be in the floating state, a proper negative voltage and a proper positive voltage are applied to the control gate VCG and the bulk VB, respectively, or a voltage of 0V is applied to the control gate VCG and a positive voltage is applied to the bulk voltage VB. Otherwise, a voltage of 0V is applied to the bulk and a negative voltage is applied to the control gate VCG. Here, in order to effectively control a threshold voltage distribution when the erasing operation is performed, the control gate voltage VCG or the bulk voltage VB may be changed during erasure.

As illustrated in FIG. 2, when the reading operation is performed in the cell array according to the present invention, a voltage of from 0.5V to 2V is applied to the bit line VD, and a voltage of from 1V to 5V is applied to the gate voltage VSG of the selection transistor to pass the bit line voltage. In addition, a voltage of from 0V to 5V is applied to the control gate VCG, a voltage of 0V is applied to the source VS, and a voltage of from −3V to 0V is applied to the bulk VB to perform the reading operation. Here, the control gate voltage VCG is properly controlled and applied according to a value of an erasure threshold voltage so as to enable a drain current to flow the erased cell. Here, when a number of threshold voltages exist because the programming operation is performed in multi levels, a number of gate voltages may be applied according to a value of each of the multi levels. Otherwise, a control gate voltage is applied and differences between the multi levels are sensed to read the data.

As described above, when data is stored in the NOR memory cell according to the present invention, or the stored data is read or erased, operations are performed with a low current and a low voltage. Therefore, more stable high-speed reading and writing operations can be simultaneously implemented. In addition, there are advantages in that reliability of a cell can be improved by the selection transistor, a chip area can be reduced due to a decrease in an area of a circuit region, and microfabrication can be easily performed by improving the scalability of the cell.

While the present invention has been particularly shown and described with reference to exemplary embodiments thereof, it will be understood by those skilled in the art that various changes in form and details may be made therein without departing from the spirit and scope of the present invention as defined by the appended claims.

What is claimed is:

1. A 2T (2-transistor) NOR-type non-volatile memory cell array which includes at least a cell, and a cell comprising:
a selection transistor which has a terminal connected to a bit line and a gate terminal applied with a selection signal; and
a storage transistor which has a terminal connected to the other terminal of the selection transistor, the other terminal connected to a common source line, and a gate applied with a control voltage,
wherein a back bias voltage is applied to a bulk region of the selection transistor and the storage transistor when a programming operation is performed, and a floating gate or a charge storage dielectric is provided between the gate of the storage transistor and the bulk region.

2. The 2T NOR-type memory cell array of claim 1, wherein the charge storage dielectric is made of a material including one or more oxide layers and one or more nitride layers, or a material including tetrahedral amorphous carbon and one or more oxide layers.

3. The 2T NOR-type memory cell array of claim 2, wherein the charge storage dielectric is one of an ON (oxide-nitride) layer, an ONO (oxide-nitride-oxide) layer, and a TAC-O (tetrahedral amorphous carbon-oxide) layer.

4. The 2T NOR-type memory cell array of claim 1, wherein a gate dielectric of the selection transistor is a single oxide layer or is the same as the charge storage dielectric.

5. A method of processing data of a 2T NOR-type non-volatile memory which includes a selection transistor that has a terminal applied with a first voltage VD and a gate applied with a selection signal VSG, and a storage transistor that has a terminal connected to the other terminal of the selection transistor, the other terminal applied with a second voltage VS, and a gate applied with a control signal VCG, the method comprising applying a third voltage VB to a bulk region of the section transistor and a bulk region of the storage transistor, storing data in the storage transistor by using a hot carrier injection method, and reading or erasing the stored data.

6. The method of claim 5, wherein one or more levels of the first voltage, the second voltage, the third voltage, and the voltage level of the control signal are changed during operation.

7. The method of claim 5, wherein, when the selection transistor and the storage transistor are N-type transistors and data is to be stored in the storage transistor, a voltage level of the first voltage ranges from 1V to 5V, a voltage level of the selection signal ranges from 3V to 9V, a voltage level of the control signal ranges from 31 3V to 9V, a voltage level of the second voltage ranges from 0to 3V, and a voltage level of the third voltage ranges from −4V to 0V.

8. The method of claim 7, wherein the voltage level of the control signal may be changed in a range of from an initial voltage level Vi to a final voltage level Vf to store data.

9. The method of claim 8, wherein the initial voltage level ranges from −3V to 3V, and the final voltage level ranges from 0V to 9V.

10. The method of claim 5, wherein when the data stored in the storage transistor is to be read, a voltage level of the first voltage ranges from 0.5 to 2V, a voltage level of the selection signal ranges from 1V to 5V, a voltage level of the control signal ranges from 0V to 5V, a voltage level of the second voltage is 0V, and a voltage level of the third voltage ranges from −3V to 0V.

11. The method of claim 5, wherein the data stored in the storage transistor is to be erased, the first voltage is in the floating state, the selection signal is in the floating state, a voltage level of the control signal ranges from −16V to 0V, the second voltage is in a floating state, and a voltage level of the third voltage ranges from 0V to 20V.

12. The method of claim 11, wherein one or more of the control signal and the third voltage are changed in a range of from an initial voltage level to a final voltage level to erase the data stored in the storage transistor.

13. The method of claim 12,
wherein the initial voltage level of the control signal is 0V, and the final voltage level ranges from −4V to −10V, and
wherein the initial voltage level of the third voltage ranges from a voltage Vcc (a power source voltage of a non-volatile memory circuit) to 10V, and the final voltage level ranges from 8V to 20V.

14. The method of claim 12, wherein the third voltage is 0V when the initial voltage level of the control signal ranges from −16V to −8V.
